(19) United States
(12) Patent Application Publication
(10) Pub. No.: US 2025/0273260 A1
(43) Pub. Date: Aug. 28, 2025

(54) MEMORY AND DATA OPERATION METHOD THEREFOR, AND ELECTRONIC DEVICE

(71) Applicant: CXMT Corporation, Hefei City (CN)

(72) Inventor: Qinghua HAN, Hefei City (CN)

(73) Assignee: CXMT Corporation, Hefei City (CN)

(21) Appl. No.: 19/204,559

(22) Filed: May 11, 2025

Related U.S. Application Data
(63) Continuation of application No. PCT/CN2023/132140, filed on Nov. 16, 2023.

(30) Foreign Application Priority Data
Aug. 2, 2023 (CN) 202310976027.3

(51) Int. Cl. G11C 11/4091; G11C 11/408; G11C 11/4096

(52) U.S. Cl. CPC G11C 11/4091; G11C 11/4085; G11C 11/4096

(57) ABSTRACT

The present disclosure provides a memory and a data operation method therefor, and an electronic device. Each storage unit of the memory includes a write transistor and a read transistor, a first source/drain of the write transistor is connected to the gate of the read transistor, each first bit line is connected to second sources/drains of one row of write transistors, and each second bit line is connected to first sources/drains of one row of read transistors. The gates in a former column of write transistors and second sources/drains in a latter column of read transistors share the same word line.

### CROSS-REFERENCE TO RELATED APPLICATIONS

This is a continuation application of International Patent Application No. PCT/CN2023/132140 filed on Nov. 16, 2023, which claims priority to Chinese Patent Application No. 202310976027.3 filed on Aug. 2, 2023. The disclosures of the above-referenced applications are hereby incorporated by reference in their entirety.

### BACKGROUND

As semiconductor technologies develop, memories, especially a dynamic random access memory (Dynamic Random Access Memory, DRAM for short), are widely applied in various electronic devices because the memories have a relatively high storage density and a relatively fast read/write speed. The dynamic random access memory includes multiple storage units, and each storage unit usually includes one transistor (Transistor) and one capacitor (Capacitor), forming a 1 Transistor 1 Capacitor (1T1C) structure.

In the foregoing storage unit with the 1T1C structure, the capacitor manufactured in this process occupies a relatively large area, which is inconducive to miniaturization of the size. In this case, the storage unit may further adopt a 2 Transistors 0 Capacitor (2T0C) structure, that is, the storage unit includes two transistors, and a first source/drain of one transistor is connected to the gate of the other transistor to remove the capacitor. However, other electrodes of the two transistors in the storage unit with the 2T0C structure need to be connected through a lead (a word line or a bit line), which makes the structure of the dynamic random access memory complex and inconvenient for the arrangement (array) of the storage unit.

### SUMMARY

In view of the foregoing problem, embodiments of the present disclosure provide a memory and a data operation method therefor, and an electronic device, so as to simplify the structure of the memory.

The present disclosure relates to the field of semiconductor technologies, and in particular, to a memory and a data operation method therefor, and an electronic device.

According to some embodiments, a first aspect of the present disclosure provides a memory, including:
multiple storage units arranged in an array, where each of the storage units includes a write transistor and a read transistor, and a first source/drain of the write transistor is connected to the gate of the read transistor;
multiple first bit lines, where each of the first bit lines is correspondingly connected to second sources/drains of the write transistors of one row of the storage units;
multiple second bit lines, where each of the second bit lines is correspondingly connected to first sources/drains of the read transistors of one row of the storage units; and
multiple word lines, where the word lines are correspondingly electrically coupled to the multiple storage units arranged in columns, and in two adjacent columns of the storage units, the gates of the write transistors in a former column of the storage units and second sources/drains of the read transistors in a latter column of the storage units are coupled to the same one of the word lines.

The memory in this embodiment of the present disclosure includes the multiple storage units arranged in an array, the multiple first bit lines, the multiple second bit lines, and the multiple word lines, and each of the word lines is electrically coupled to the multiple of the storage units arranged in a column. In the two adjacent columns of the storage units, the gates of the write transistors in a former column of the storage units and second sources/drains of the read transistors in a latter column of the storage units are coupled to the same one of the word lines, so that the word line serves as a write word line of a connected write transistor and a read word line of a connected read transistor. The two adjacent columns of the storage units share one word line, so as to reduce the quantity of word lines, simplify the architecture of the memory, and reduce the complexity of an array fabrication procedure of the storage units.

According to some embodiments, a second aspect of the present disclosure provides an electronic device, including the foregoing memory. Therefore, the electronic device has at least advantages of a simplified architecture and a simple fabrication procedure of the memory. For a specific effect, refer to the foregoing descriptions. Details are not described herein again.

According to some embodiments, a third aspect of the present disclosure provides a data operation method for a memory, where the data operation method is applied to the foregoing memory, and the data operation method includes the step as follows.

A data write operation or a data read operation is performed on a column of the storage units.

In some possible examples, that a data write operation is performed on a column of the storage units includes the steps as follows.

A first voltage is applied to a word line coupled to the gates of write transistors in the column of the storage units, data signals are separately applied to multiple first bit lines to turn on the write transistors in the column of the storage units, and the data signal is written to the gates of read transistors in the column of the storage units; and a first reference voltage is applied to the word line other than the word line coupled to the gates of the write transistors in the column of the storage units, and complementary signals of the data signals are separately applied to multiple second bit lines, so as to turn off the write transistors in columns of the storage units other than the column of the storage units and turn off the read transistors in each column of the storage units.

In summary, the data operation method in this embodiment of the present disclosure is applied to the foregoing memory, so that the data write operation or the data read operation is performed on the column of the storage units in the foregoing memory, and the architecture of the memory is simplified and the complexity is reduced.

### BRIEF DESCRIPTION OF DRAWINGS

FIG. 1 is a schematic diagram of a storage unit in a related technology;

FIG. 2 is a schematic diagram of a memory according to an embodiment of the present disclosure;

FIG. 3 is a schematic diagram of a data write operation for a memory according to an embodiment of the present disclosure;

FIG. 4 is a diagram of a specific procedure of a data write operation for a memory according to an embodiment of the present disclosure;

FIG. 5 is a schematic diagram of a data read operation for a memory according to an embodiment of the present disclosure; and

FIG. 6 is a diagram of a specific procedure of a data read operation for a memory according to an embodiment of the present disclosure.

### DESCRIPTIONS OF REFERENCE NUMERALS

| | |
|---|---|
| 10-memory; | 11-storage unit; |
| 12-write transistor; | 13-read transistor; |
| 14-word line; | 15-first bit line; |
| 16-second bit line; | 17-sense amplifier. |

### DETAILED DESCRIPTION

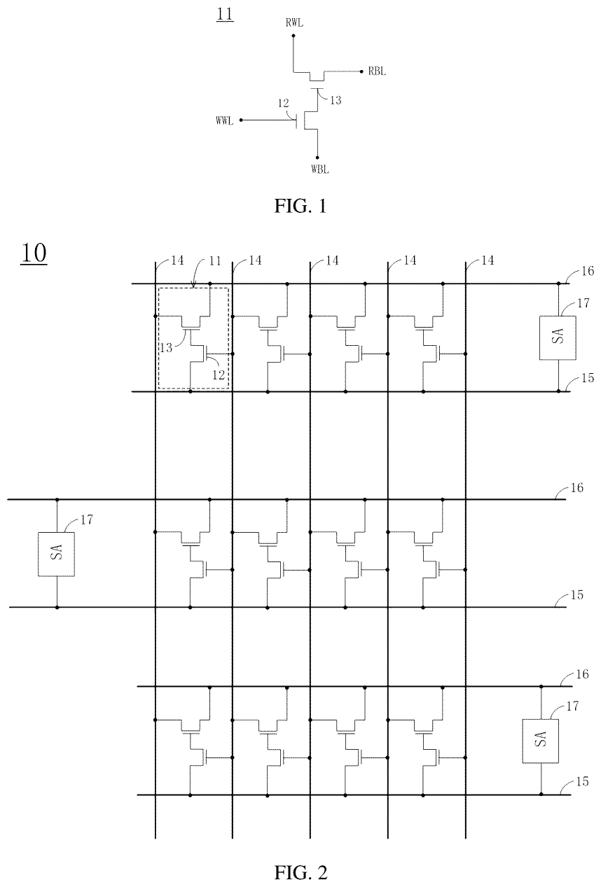

A problem of a complex memory structure exists in the related technology. It is discovered by the inventor that a reason is as follows: Referring to FIG. 1, a storage unit 11 includes a read transistor (Read Transistor) 13 and a write transistor (Write Transistor) 12. A first source/drain of the write transistor 12 is connected to the gate of the read transistor 13, the first source/drain of the write transistor 12 is connected to a write bit line (Write Bit Line, WBL for short), and the gate of the write transistor 12 is connected to a write word line (Write Word Line, WWL for short). A first source/drain of the read transistor 13 is connected to a read bit line (Read Bit Line, RBL for short), and a second source/drain of the read transistor 13 is connected to a read word line (Read Word Line, RWL for short). Each storage unit 11 needs four types of leads (the write bit line, the write word line, the read bit line, and the read word line), and the structure of the memory is complex.

An embodiment of the present disclosure provides a memory. Two adjacent columns of storage units in the memory share one word line. The gates in a former column of write transistors and second sources/drains in a latter column of read transistors are coupled to the same word line, so that the word line serves as a write word line of connected write transistors and a read word line of connected read transistors, so as to reduce the quantity of word lines, simplify the architecture of the memory, and reduce the complexity of an array fabrication procedure of storage units.

To make the foregoing objects, features, and advantages of the embodiments of the present disclosure clearer and easier to understand, the technical solutions in the embodiments of the present disclosure are clearly described below with reference to the accompanying drawings in the embodiments of the present disclosure. Clearly, the described embodiments are merely some rather than all of the embodiments of the present disclosure. Based on the embodiments of the present disclosure, all other embodiments obtained by a person of ordinary skill in the art without creative efforts fall within the protection scope of the present disclosure.

Referring to FIG. 2, an embodiment of the present disclosure provides a memory 10, and the memory 10 includes multiple storage units 11 arranged in an array. For example, the multiple storage units 11 are disposed at intervals and arranged in multiple rows and multiple columns, a row direction is a horizontal direction shown in FIG. 2, and a column direction is shown in a vertical direction shown in FIG. 2.

As shown in FIG. 2, each of the storage units 11 includes a write transistor 12 and a read transistor 13, and a first source/drain of the write transistor 12 is connected to the gate of the read transistor 13. The gate of the read transistor 13 serves as a storage node (Storage Node) to store data, for example, store data “1” or data “0”. The storage unit 11 is a 2T0C storage unit 11, reducing the volume of the storage unit 11, and improving the storage density.

The memory 10 further includes multiple first bit lines 15 and multiple second bit lines 16. The multiple first bit lines 15 are disposed at intervals, and each of the first bit lines 15 is correspondingly connected to second sources/drains of the write transistors 12 of one row of the storage units 11. The multiple second bit lines 16 are disposed at intervals, and each of the second bit line 16 is correspondingly connected to first sources/drains of the read transistors 13 of one row of the storage units 11. A data write operation is performed on the storage node by utilizing the write transistor 12, or a data read operation is performed on the storage node by utilizing the read transistor 13.

The multiple first bit lines 15 and the multiple second bit lines 16 all extend along the row direction (the horizontal direction shown in FIG. 2) of an array formed by the multiple storage units 11. Each of the first bit lines 15 and each of the second bit lines 16 are respectively located on two sides of one row of storage units 11, and are correspondingly connected to the row of storage units 11. Each of the first bit lines 15 serves as a write bit line of the connected write transistors 12, and each of the second bit lines 16 serves as a read bit line of the connected read transistors 13.

The memory 10 further includes multiple word lines 14, and the word lines 14 are correspondingly electrically coupled to the multiple storage units 11 arranged in columns. In two adjacent columns of the storage units 11, the gates in a former column of write transistors 12 and second sources/drains in a latter column of read transistors 13 are coupled to the same word line 14. Former and latter directions are shown in the left and right directions in FIG. 2, the former column is a left column of two adjacent columns, and the latter column is a right column of the two adjacent columns.

Turn-on or turn-off of the write transistor 12 and the read transistor 13 is controlled by each of the word lines 14. In addition, two adjacent storage units 11 share one word line 14, that is, one word line 14 serves as a write word line of the connected write transistors 12 and a read word line of the connected read transistors 13, so as to reduce the quantity of the word lines 14, simplify the architecture of the memory 10, and reduce the complexity of an array fabrication procedure of the storage units 11.

Controlling voltages of each word line 14, each first bit line 15, and each second bit line 16 may control turn-on or turn-off of each write transistor 12, and turn-on or turn-off of each read transistor 13, so as to write data to the storage node or read data in the storage node. A data write operation or a data read operation may be performed on a column of data units by utilizing each of the word lines 14, so as to write data of each of the first bit lines 15 to a corresponding storage node, or read data of the storage node to a corresponding second bit line 16.

The gate of each read transistor 13 in the storage units 11 is a storage node, and types of the read transistor 13 and the write transistor 12 are the same. For example, both the read transistor 13 and the write transistor 12 are N-type transistors, or both the read transistor 13 and the write transistor 12 are P-type transistors. When both the read transistor 13 and the write transistor 12 are N-type transistors, the voltages on each word line 14, each first bit line 15, and each second bit line 16 are adapted to an N-type transistor, so as to turn on or turn off each read transistor 13 and the write transistor 12. When both the read transistor 13 and the write transistor 12 are P-type transistors, the voltages on each word line 14, each first bit line 15, and each second bit line 16 are adapted to the P-type transistor, so as to turn on or turn off each read transistor 13 and the write transistor 12.

In some examples, the multiple word lines 14 include multiple first word lines and two second word lines, and each of the first word lines is correspondingly connected to the gates of the write transistors 12 in the former column of the storage units 11 and the second sources/drains of the read transistors 13 in the latter column of the storage units 11 in the two adjacent columns of the storage units 11; and one of the two second word lines is connected to the second sources/drains of the read transistors 13 in one outermost column of the storage units 11, and the other of the two second word lines is connected to the gates of the write transistors 12 in the other outermost column of the storage units 11.

The word line 14 located between the two adjacent columns of the storage units 11 is a first word line, that is, the two adjacent columns of the storage units 11 may share one word line 14. The read transistors 13 or the write transistors 12 in each of the outermost two columns of the storage units 11 need to be separately connected to the word line 14, and the word line 14 is a second word line. As shown in FIG. 2, the read transistors 13 of the leftmost column of storage units 11 and the write transistors 12 of the rightmost column of storage units 11 are each connected to one second word line.

The second word line connected to the read transistors 13 in the former column of the storage units 11 serves as a read word line of the connected read transistors 13, and the second word line connected to the write transistors 12 in the latter column of the storage units 11 serves as a write word line of the connected write transistors 12.

In some examples, the memory 10 further includes multiple sense amplifiers (Sense Amplifier, SA for short) 17, and each of the sense amplifiers 17 is correspondingly connected between the first bit line 15 and the second bit line 16 corresponding to one row of the storage units 11; and each of the sense amplifiers 17 is configured to: when a data read operation is performed, sense and amplify the difference between the voltages on the corresponding first bit line 15 and the corresponding second bit line 16, so as to read data stored in the storage units 11 from the second bit line 16.

One sense amplifier 17 is connected between the corresponding first bit line 15 and the corresponding second bit line 16, and is configured to sense and amplify the difference between the voltages on the first bit line 15 and the second bit line 16 connected to the sense amplifier. When the data read operation is performed, the voltages on the corresponding first bit line 15 and the corresponding second bit line 16 are different, and the sense amplifier 17 senses the voltage difference and amplifies the voltage difference. For example, when the voltage on the second bit line 16 is less than the voltage on the first bit line 15, the voltage on the second bit line 16 is made much less than the voltage on the first bit line 15 by pulling down the voltage on the second bit line 16 and/or pulling up the voltage on the first bit line 15. When the voltage on the second bit line 16 is greater than the voltage on the first bit line 15, the voltage on the second bit line 16 is made much greater than the voltage on the first bit line 15 by pulling up the voltage on the second bit line 16 and/or pulling down the voltage on the first bit line 15. Therefore, it is convenient to read the data stored in the storage units 11 from the second bit line 16.

In conclusion, the memory 10 in this embodiment of the present disclosure includes multiple storage units 11 arranged in an array, multiple first bit lines 15, multiple second bit lines 16, and multiple word lines 14, and each of the word lines 14 is correspondingly electrically coupled to the multiple storage units 11 arranged in a column. In two adjacent columns of the storage units 11, the gates in a former column of write transistors 12 and second sources/drains in a latter column of read transistors 13 are coupled to the same word line 14, so that the word line 14 serves as a write word line of the connected write transistors 12 and a read word line of the connected read transistors 13. The two adjacent columns of the storage units 11 share one word line 14, so as to reduce the quantity of the word lines 14, simplify the architecture of the memory 10, and reduce the complexity of the array fabrication procedure of the storage units 11.

It should be noted that in the present disclosure, the concepts of “row” and “column” are relative, that is, “row” and “column” are interchangeable. In addition, in the present disclosure, the positive and negative signs are taken into consideration when the magnitudes of voltages are compared.

An embodiment of the present disclosure further provides an electronic device. The electronic device may be a computer, a server, or the like. The electronic device includes the foregoing memory 10 (refer to FIG. 2). Therefore, the electronic device has at least advantages of a simplified architecture and a simple fabrication procedure of the memory 10. For a specific effect, refer to the foregoing descriptions. Details are not described herein again.

The electronic device may further include at least one processor, so as to execute computer-executable instructions stored in the memory 10. The processor may be a central processing unit (Central Processing Unit, CPU for short), a network processor (Network Processor, NP for short), a digital signal processor (Digital Signal Processor, DSP for short), an application-specific integrated circuit (Application-Specific Integrated Circuit, ASIC for short), another programmable logic device, or the like.

For example, the electronic device includes but is not limited to a server, a printer, a scanner, a tablet computer, a smartphone, a dashcam, a navigator, and a wearable device.

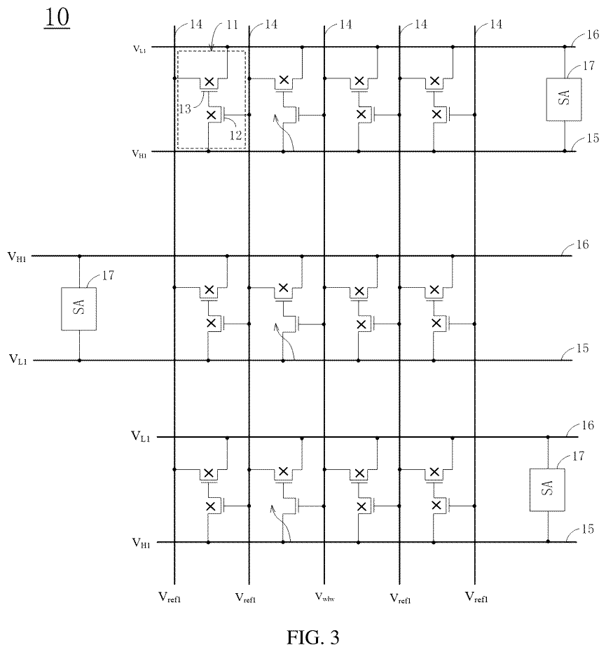

An embodiment of the present disclosure further provides a data operation method for a memory. Referring to FIG. 3 to FIG. 6, the data operation method is applied to the foregoing memory 10. The data operation method includes the step as follows. A data write operation or a data read operation is performed on a column of the storage units 11, so as to store data at the gate of a read transistor 13 in each of the column of the storage units 11, or read data stored at the gate of a read transistor 13 in each of the column of the storage units 11.

In some examples, referring to FIG. 3, that a data write operation is performed on a column of the storage units 11 includes the steps as follows. A first voltage is applied to a word line 14 coupled to the gates of write transistors 12 in the column of the storage units 11, data signals are separately applied to multiple first bit lines 15 to turn on the write transistors 12 in the column of the storage units 11, and the data signal is written to the gates of the read transistors 13 in the column of the storage units 11.

The first voltage may be denoted as V_{wlw}, and the first voltage may enable all the write transistors 12 in the column of the storage units 11 to turn on. The data signal may be a first high-level signal or a first low-level signal, that is, may be one of the first high-level signal and the first low-level signal. The voltages of the first high-level signal and the first low-level signal are respectively denoted as V_{H1} and V_{L1}. For example, when the data signal is the first high-level signal, data “1” is stored in a storage node by utilizing the turned-on write transistor 12, and when the data signal is the first low-level signal, data “0” is stored in the storage node by utilizing the turned-on write transistor 12. Alternatively, when the data signal is the first high-level signal, data “0” is stored in the storage node by utilizing the turned-on write transistor 12, and when the data signal is the first low-level signal, data “1” is stored in the storage node by utilizing the turned-on write transistor 12.

That a data write operation is performed on a column of the storage units 11 further includes the steps as follows. A first reference voltage is applied to the word line 14 other than the word line 14 coupled to the gates of the write transistors 12 in the column of the storage units 11, and complementary signals of the data signals are separately applied to multiple second bit lines 16, so as to turn off the write transistors 12 in columns of the storage units 11 other than the column of the storage units 11 and turn off the read transistors 13 in each column of the storage units 11.

The first reference voltage may be denoted as V_{ref1}, and the first reference voltage enables all the write transistors 12 in the columns of the storage units 11 to turn off. The complementary signal is complementary to the data signal. The complementary signal and the data signal are respectively the first high-level signal and the first low-level signal, that is, the data signal is one of the first high-level signal and the first low-level signal, and the complementary signal is the other of the first high-level signal and the first low-level signal.

In some possible implementations, both the read transistor 13 and the write transistor 12 are N-type transistors, and the difference between the first voltage and the voltage of the data signal (including the first high-level signal and the first low-level signal) is greater than a threshold voltage of the write transistor 12, so as to turn on the write transistor 12 coupled to the word line 14 to which the first voltage is applied; and the difference between the first reference voltage and the voltage of the data signal (including the first high-level signal and the first low-level signal) is less than the threshold voltage of the write transistor 12, so as to turn off the write transistor 12 coupled to the word line 14 to which the first reference voltage is applied.

The threshold voltage of the write transistor 12 is denoted as V_{tw}, and a threshold voltage of the read transistor 13 is denoted as Vₜᵣ. The difference is a value obtained by subtracting the latter from the former, and the difference between the first voltage and the voltage of the data signal is equal to a value obtained by subtracting the voltage of the data signal from the first voltage. For the difference in the following, refer to the meaning herein.

When both the read transistor 13 and the write transistor 12 are N-type transistors, both the threshold voltage of the write transistor 12 and the threshold voltage of the read transistor 13 are greater than zero. The difference between the first voltage and the voltage of the data signal is greater than the threshold voltage of the write transistor 12, so as to turn on the write transistor 12 coupled to the word line 14 to which the first voltage is applied, so as to write data on the first bit line 15 to the storage node. The difference between the first reference voltage and the voltage of the data signal is less than the threshold voltage of the write transistor 12, so as to turn off the write transistor 12 coupled to the word line 14 to which the first reference voltage is applied, that is, the data write operation is not performed on the columns of the storage units 11.

The data signal is one of the first high-level signal or the first low-level signal, and the voltage of the first high-level signal is greater than the voltage of the first low-level signal. When the difference between the first voltage and the voltage of the first high-level signal is greater than the threshold voltage of the write transistor 12, that is, V_{wlw}−V_{H1}>V_{tw}, this column of write transistors 12 coupled to the word line 14 to which the first voltage is applied are turned on. When the difference between the first reference voltage and the voltage of the first low-level signal is less than the threshold voltage of the write transistor 12, that is, V_{ref1}−V_{L1}<V_{tw}, this column of write transistors 12 coupled to the word line 14 to which the first reference voltage is applied are turned off.

When the data write operation is performed on a column of the storage units 11, each read transistor 13 is turned off. To be specific, when the write transistor 12 coupled to the word line 14 to which the first voltage is applied is turned on, and the write transistor 12 coupled to the word line 14 to which the first reference voltage is applied is turned off, each read transistor 13 is turned off. For example, the difference between the voltage of the first high-level signal and the voltage of the first low-level signal is less than the threshold voltage of the read transistor 13, and the difference between the voltage of the first high-level signal and the first reference voltage is less than the threshold voltage of the read transistor 13, so as to turn off each read transistor 13. That is, V_{H1}−V_{L1}<Vₜᵣ, and V_{H1}−V_{ref1}<Vₜᵣ, so as to ensure that each read transistor 13 is turned off. The first reference voltage may be between the voltage of the first high-level signal and the voltage of the first low-level signal, that is, the first reference voltage is less than the voltage of the first high-level signal and greater than the voltage of the first low-level signal.

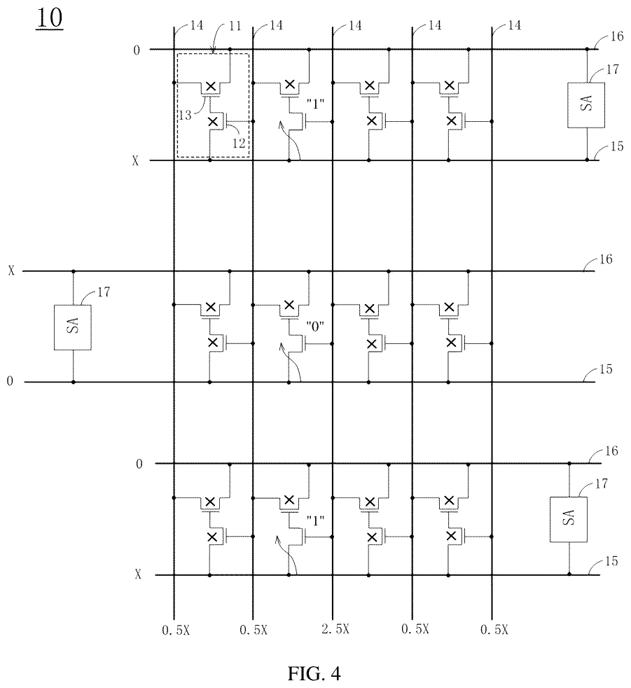

For example, referring to FIG. 4, the threshold voltage of the write transistor 12 is X (X>0), the voltage of the read transistor 13 is 1.5X, the first voltage is 2.5X, the first reference voltage is 0.5X, the voltage of the first high-level signal is X, and the voltage of the first low-level signal is 0, that is, V_{tw}=X, Vₜᵣ=1.5X, V_{wlw}=2.5X, V_{ref1}=0.5X, V_{H1}=X, and V_{L1}=0. In this case, the first high-level signal or the first low-level signal on the first bit line 15 is written into a corresponding storage unit 11 in the column of the storage units 11 coupled to the word line 14 to which the first voltage is applied. It should be noted that the embodiments of the present disclosure include but are not limited thereto.

In some possible implementations, both the read transistor 13 and the write transistor 12 are P-type transistors, and the difference between the first voltage and the voltage of the data signal is less than the threshold voltage of the write transistor 12, so as to turn on the write transistor 12 coupled to the word line 14 to which the first voltage is applied; the difference between the first reference voltage and the voltage of the data signal is greater than the threshold voltage of the write transistor 12, so as to turn off the write transistor 12 coupled to the word line 14 to which the first reference voltage is applied; and
the data signal is one of the first high-level signal and the first low-level signal, the complementary signal is the other of the first high-level signal and the first low-level signal, the difference between the voltage of the first low-level signal and the voltage of the first high-level signal is greater than the threshold voltage of the read transistor 13, and the difference between the voltage of the first low-level signal and the first reference voltage is greater than the threshold voltage of the read transistor 13, so as to turn off each of the read transistors 13.

When both the read transistor 13 and the write transistor 12 are P-type transistors, both the threshold voltage of the write transistor 12 and the threshold voltage of the read transistor 13 are less than zero. The difference between the first voltage and the voltage of the data signal is less than the threshold voltage of the write transistor 12, so as to turn on the write transistor 12 coupled to the word line 14 to which the first voltage is applied, so as to write data on the first bit line 15 to the storage node. The difference between the first reference voltage and the voltage of the data signal is greater than the threshold voltage of the write transistor 12, so as to turn off the write transistor 12 coupled to the word line 14 to which the first reference voltage is applied, that is, the data write operation is not performed on the columns of the storage units 11.

When the difference between the first voltage and the voltage of the first high-level signal is less than the threshold voltage of the write transistor 12, that is, V_{wlw}−V_{H1}<V_{tw}, this column of write transistors 12 coupled to the word line 14 to which the first voltage is applied are turned on. When the difference between the first reference voltage and the voltage of the first high-level signal is greater than the threshold voltage of the write transistor 12, that is, V_{ref1}−V_{H1}>V_{tw}, this column of write transistors 12 coupled to the word line 14 to which the first reference voltage is applied are turned off.

When the data write operation is performed on a column of the storage units 11, each read transistor 13 is turned off. The difference between the voltage of the first low-level signal and the voltage of the first high-level signal is greater than the threshold voltage of the read transistor 13, and the difference between the voltage of the first low-level signal and the first reference voltage is greater than the threshold voltage of the read transistor 13, so as to turn off each of the read transistors 13. That is, V_{L1}−V_{H1}>Vₜᵣ, and V_{L1}−V_{ref1}>Vₜᵣ, so as to ensure that each read transistor 13 is turned off. The first reference voltage may be between the voltage of the first high-level signal and the voltage of the first low-level signal. In this case, when V_{L1}−V_{H1}<Vₜᵣ, V_{L1}−V_{ref1}<Vₜᵣ.

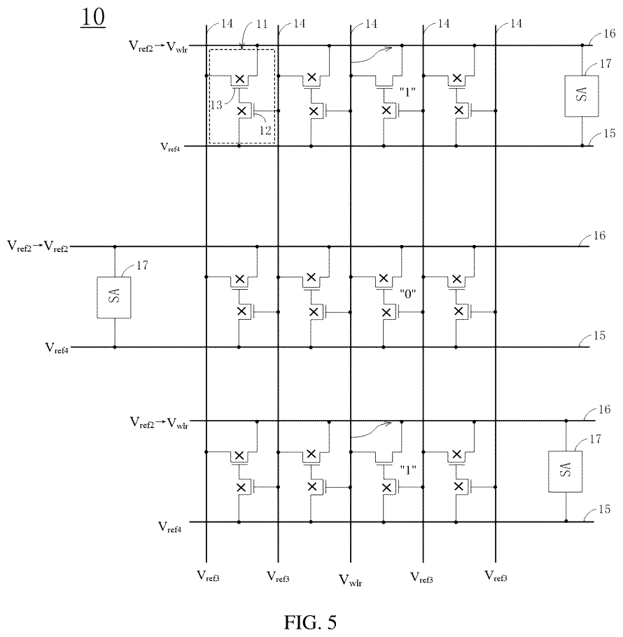

In some possible examples, referring to FIG. 5, that a data read operation is performed on a column of the storage units 11 includes the steps as follows. The multiple second bit lines 16 are precharged to a second reference voltage; a second voltage is applied to the word line 14 coupled to first sources/drains of the read transistors 13 in the column of the storage units 11, and the read transistors 13 in the column of the storage units 11 are turned on or turned off based on storage signals of the gates of the read transistors 13 in the column of the storage units 11, so as to read the storage signals of the read transistors 13 in the column of the storage units 11 to a connected one of the second bit lines 16.

The second reference voltage may be denoted as V_{ref2}, the second voltage may be denoted as V_{wlr}, and the second voltage enables all the read transistors 13 in the column of the storage units 11 to turn on. The storage signal of the gate of the read transistor 13 includes a second high-level signal and a second low-level signal, and the voltage of the second high-level signal and the voltage of the second low-level signal are respectively denoted as V_{H2} and V_{L2}. When the storage signal of the gate of the read transistor 13 is the second high-level signal, data “1” is stored at the gate of the read transistor 13, and when the storage signal of the gate of the read transistor 13 is the second low-level signal, data “0” is stored at the gate of the read transistor 13. Alternatively, when the storage signal of the gate of the read transistor 13 is the second high-level signal, data “0” is stored at the gate of the read transistor 13, and when the storage signal of the gate of the read transistor 13 is the second low-level signal, data “1” is stored at the gate of the read transistor 13.

The voltage of the storage signal of the gate of the read transistor 13 is compared with the second reference voltage, so that the read transistor 13 is turned on or turned off. For example, in a case in which the read transistor 13 is an N-type transistor, when the storage signal of the gate of the read transistor 13 is the second high-level signal, the read transistor 13 is turned on to read the second high-level signal. When the storage signal of the gate of the read transistor 13 is the second low-level signal, the read transistor 13 is turned off, and the voltage on the second bit line 16 remains unchanged, so as to read the second low-level signal.

That a data read operation is performed on a column of the storage units 11 further includes the steps as follows. A third reference voltage is applied to the word line 14 other than the word line 14 coupled to the gates of the read transistors 13 in the column of the storage units 11, and a fourth reference voltage is applied to the multiple first bit lines 15, so as to turn off the read transistors 13 in the columns of the storage units 11 other than the column of the storage units 11 and turn off the write transistors 12 in each column of the storage units 11.

The third reference voltage may be denoted as V_{ref3}, the fourth reference voltage may be denoted as V_{ref4}, read transistors 13 in other columns are turn off, and each write transistor 12 is turned off. In some possible implementations, both the read transistor 13 and the write transistor 12 are N-type transistors; the storage signal includes the second high-level signal and the second low-level signal, and the difference between the voltage of the second high-level signal and the second reference voltage is less than the threshold voltage of each of the read transistors 13, that is, V_{H2}−V_{ref2}<Vₜᵣ, so as to turn off each of the precharged read transistors 13;
when the storage signal of the gate of the read transistor 13 in each in the column of the storage units 11 is the second high-level signal, the difference between the voltage of the second high-level signal and the second voltage is greater than the threshold voltage of the read transistor 13, that is, V_{H2}−V_{wlr}>Vₜᵣ, so as to turn on the read transistor 13 whose storage signal is the second high-level signal, and the voltage of the second bit line 16 connected to the turned-on read transistor 13 changes from the second reference voltage to the second voltage; and
when the storage signal of the gate of the read transistor 13 in each of the column of the storage units 11 is the second low-level signal, the difference between the voltage of the second low-level signal and the second voltage is less than the threshold voltage of the read transistor, that is, V_{L2}−V_{wlr}<Vₜᵣ, so as to turn off the read transistor 13 whose storage signal is the second low-level signal, and the voltage of the second bit line 16 connected to the turned-off read transistor 13 maintains the second reference voltage.

The difference between the voltage of the second high-level signal and the third reference voltage is less than the threshold voltage of the read transistor 13, that is, V_{H2}-V_{ref3}<Vₜᵣ. When V_{H2}−V_{ref3}<Vₜᵣ, V_{L2}−V_{ref3}<V_{H2}−V_{ref3}<Vₜᵣ, that is, the read transistors 13 in other columns maintain turned off regardless of whether the storage signal of each of the read transistors 13 in other columns is the second high-level signal or the second low-level signal.

The difference between the third reference voltage and the voltage of the second low-level signal is less than the threshold voltage of the write transistor 12, and the difference between the third reference voltage and the fourth reference voltage is less than the threshold voltage of the write transistor 12, that is, V_{ref3}−V_{L2}<V_{tw}, and V_{ref3}−V_{ref4}<V_{tw}, so as to turn off each of the write transistors 12.

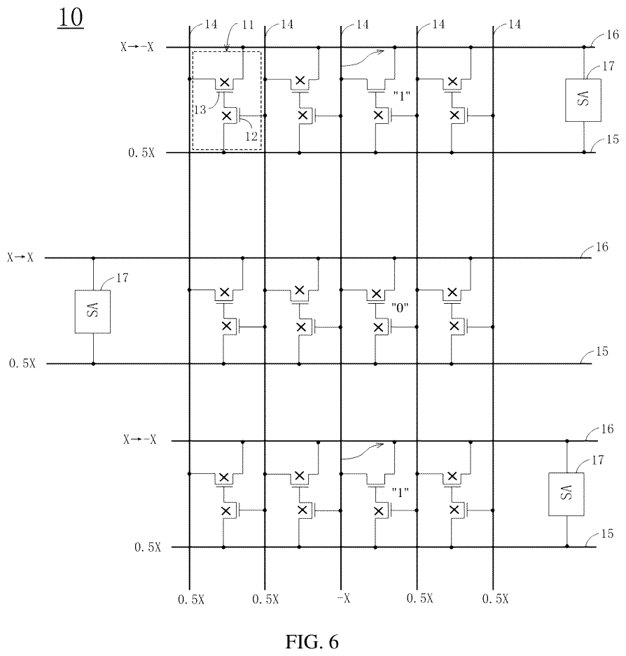

For example, referring to FIG. 6, the threshold voltage of the write transistor 12 is X (X>0), the voltage of the read transistor 13 is 1.5X, the voltage of the first high-level signal is X, the voltage of the first low-level signal is 0, the second voltage may be −X, the second reference voltage may be X, and both the third reference voltage and the fourth reference voltage are 0.5X, that is, V_{tw}=X, Vₜᵣ=1.5X, V_{wlr}=−X, V_{ref2=1}X, V_{ref3}=V_{ref4}=0.5X, V_{H2}=X, and V_{L2}=0. In this case, the storage signal in each of the storage units 11 is read to the connected second bit line 16. It should be noted that the embodiments of the present disclosure include but are not limited thereto.

In some other possible implementations, both the read transistor 13 and the write transistor 12 are P-type transistors, the storage signal includes the second high-level signal and the second low-level signal, and the difference between the voltage of the second low-level signal and the second reference voltage is greater than the threshold voltage of each of the read transistors 13, that is, V_{L2}−V_{ref2}>Vₜᵣ, so as to turn off each of the precharged read transistors 13;
when the storage signal of the gate of the read transistor 13 in each of the column of the storage units 11 is the second low-level signal, the difference between the voltage of the second low-level signal and the second voltage is less than the threshold voltage of the read transistor 13, that is, V_{L2}−V_{wlr}<Vₜᵣ, so as to turn on the read transistor 13 whose storage signal is the second low-level signal, and the voltage of the second bit line 16 connected to the turned-on read transistor 13 changes from the second reference voltage to the second voltage; and
when the storage signal of the gate of the read transistor 13 in each of the column of the storage units 11 is the second high-level signal, the difference between the voltage of the second high-level signal and the second voltage is greater than the threshold voltage of the read transistor, that is, V_{H2}−V_{wlr}>Vₜᵣ, so as to turn off the read transistor 13 whose storage signal is the second high-level signal, and the voltage of the second bit line 16 connected to the turned-off read transistor 13 maintains the second reference voltage.

The difference between the voltage of the second low-level signal and the third reference voltage is greater than the threshold voltage of the read transistor 13, that is, V_{L2}−V_{ref3}>Vₜᵣ. Further, because V_{H2}−V_{ref3}>V_{L2}−V_{ref3}>Vₜᵣ, the read transistors 13 in other columns maintain turned off regardless of whether the storage signal of each of the read transistors 13 in other columns is the second high-level signal or the second low-level signal.

The difference between the third reference voltage and the voltage of the second high-level signal is greater than the threshold voltage of the write transistor 12, and the difference between the third reference voltage and the fourth reference voltage is greater than the threshold voltage of the write transistor 12, that is, V_{ref3}−V_{H2}>V_{tw}, and V_{ref3}-V_{ref4}>V_{tw}, so as to turn off each of the write transistors 12.

In some possible examples, the third reference voltage and the fourth reference voltage are half the difference between the voltage of the second high-level signal and the voltage of the second low-level signal. The voltage of the second high-level signal may be the same as the voltage of the first high-level signal, and the voltage of the second low-level signal may be the same as the voltage of the first low-level signal.

In summary, the data operation method in this embodiment of the present disclosure is applied to the foregoing memory 10, so that the data write operation or the data read operation is performed on the column of the storage units 11 in the foregoing memory, and the architecture of the memory 10 is simplified and the complexity is reduced.

The embodiments and the implementations in this specification are described in a progressive manner. Each embodiment focuses on a difference from other embodiments. Refer to the embodiments for same or similar parts in the embodiments. Descriptions with reference to terms “one embodiment”, “some embodiments”, “example implementation”, “example”, “specific example”, “some examples”, or the like means that specific features, structures, materials, or characteristics described with reference to implementations or examples are included in at least one implementation or example of the present disclosure. In this specification, a schematic description of the foregoing term does not necessarily refer to the same implementation or an example. Further, specific features, structures, materials, or characteristics described may be properly combined in any one or more implementations or examples.

Finally, it should be noted that the foregoing embodiments are merely intended for describing the technical solutions of the present disclosure, but not for limiting the present disclosure. Although the present disclosure is described in detail with reference to the foregoing embodiments, persons of ordinary skill in the art should understand that they may still make modifications to the technical solutions described in the foregoing embodiments or make equivalent replacements to some or all technical features thereof. However, these modifications or replacements do not make the essence of the corresponding technical solutions depart from the scope of the technical solutions in the embodiments of the present disclosure.

What is claimed is:

1. A memory, comprising:
a plurality of storage units arranged in an array, each of the storage units comprising a write transistor and a read transistor, and a first source/drain of the write transistor being connected to a gate of the read transistor;
a plurality of first bit lines, each of the first bit lines being correspondingly connected to second sources/drains of the write transistors of one row of the storage units;
a plurality of second bit lines, each of the second bit lines being correspondingly connected to first sources/drains of the read transistors of one row of the storage units; and
a plurality of word lines, the word lines being correspondingly electrically coupled to the storage units arranged in columns, wherein in two adjacent columns of the storage units, gates of the write transistors in a former column and second sources/drains of the read transistors in a latter column are coupled to a same one of the word lines.

2. The memory according to claim 1, wherein the plurality of word lines comprise a plurality of first word lines and two second word lines, and each of the first word lines is correspondingly connected to the gates of the write transistors in the former column of the storage units and the second sources/drains of the read transistors in the latter column of the storage units in the two adjacent columns of the storage units; and
one of the two second word lines is connected to the second sources/drains of the read transistors in one outermost column of the storage units, and the other of the two second word lines is connected to the gates of the write transistors in the other outermost column of the storage units.

3. The memory according to claim 1, wherein the memory further comprises a plurality of sense amplifiers, and each of the sense amplifiers is connected to the first bit line and the second bit line corresponding to one row of the storage units; and
each of the sense amplifiers is configured to: when a data read operation is performed, sense and amplify a difference between voltages on the corresponding first bit line and the corresponding second bit line, so as to read data stored in the storage units from the second bit line.

4. The memory according to claim 1, wherein the gate of the read transistor is a storage node, and both the read transistor and the write transistor are N-type transistors, or both the read transistor and the write transistor are P-type transistors.

5. An electronic device, comprising the memory according to claim 1.

6. A data operation method for a memory, applied to the memory according to claim 1, and the data operation method comprising:
performing a data write operation or a data read operation on a column of the storage units.

7. The data operation method according to claim 6, wherein performing the data write operation on the column of the storage units comprises:
applying a first voltage to a word line coupled to gates of write transistors in the column of the storage units, and separately applying data signals to the plurality of first bit lines, so as to turn on the write transistors in the column of the storage units, and to write the data signals to gates of read transistors in the column of the storage units; and
applying a first reference voltage to word lines other than the word line coupled to the gates of the write transistors in the column of the storage units, and separately applying complementary signals of the data signals to the plurality of second bit lines, so as to turn off the write transistors in columns of the storage units other than the column of the storage units and to turn off the read transistors in each column of the storage units.

8. The data operation method according to claim 7, wherein both the read transistor and the write transistor are N-type transistors, and a difference between the first voltage and a voltage of the data signal is greater than a threshold voltage of the write transistor, so as to turn on the write transistor coupled to the word line to which the first voltage is applied;
a difference between the first reference voltage and the voltage of the data signal is less than the threshold voltage of the write transistor, so as to turn off the write transistor coupled to the word line to which the first reference voltage is applied; and
the data signal is one of a first high-level signal and a first low-level signal, the complementary signal is the other of the first high-level signal and the first low-level signal, a difference between a voltage of the first high-level signal and a voltage of the first low-level signal is less than a threshold voltage of the read transistor, and a difference between the voltage of the first high-level signal and the first reference voltage is less than the threshold voltage of the read transistor, so as to turn off each of the read transistors.

9. The data operation method according to claim 7, wherein both the read transistor and the write transistor are P-type transistors, and a difference between the first voltage and a voltage of the data signal is less than the threshold voltage of the write transistor, so as to turn on the write transistor coupled to the word line to which the first voltage is applied;
a difference between the first reference voltage and the voltage of the data signal is greater than the threshold voltage of the write transistor, so as to turn off the write transistor coupled to the word line to which the first reference voltage is applied; and
the data signal is one of a first high-level signal and a first low-level signal, the complementary signal is the other of the first high-level signal and the first low-level signal, the difference between a voltage of the first low-level signal and a voltage of the first high-level signal is greater than the threshold voltage of the read transistor, and a difference between the voltage of the first low-level signal and the first reference voltage is greater than the threshold voltage of the read transistor, so as to turn off each of the read transistors.

10. The data operation method according to claim 7, wherein performing the data read operation on the column of the storage units comprises:
precharging the plurality of second bit lines to a second reference voltage;
applying a second voltage to the word line coupled to first sources/drains of the read transistors in the column of the storage units, so that the read transistors in the column of the storage units are turned on or off based on storage signals of the gates of the read transistors in the column of the storage units, so as to read the storage signals of the gates of the read transistors in the column of the storage units into the second bit lines correspondingly; and
applying a third reference voltage to word lines other than the word line coupled to the gates of the read transistors in the column of the storage units, and applying a fourth reference voltage to the plurality of first bit lines, so as to turn off the read transistors in columns of the storage units other than the column of the storage units and to turn off the write transistors in each column of the storage units.

11. The data operation method according to claim 10, wherein both the read transistor and the write transistor are N-type transistors;
the storage signal comprises a second high-level signal and a second low-level signal, and a difference between a voltage of the second high-level signal and the second reference voltage is less than the threshold voltage of each of the read transistors, so as to turn off each of the precharged read transistors;
when the storage signal of the gate of the read transistor in the column of the storage units is the second high-level signal, a difference between the voltage of the second high-level signal and the second voltage is greater than the threshold voltage of the read transistor, so as to turn on the read transistor whose storage signal is the second high-level signal, and a voltage of the second bit line connected to the turned-on read transistor changes from the second reference voltage to the second voltage; and
when the storage signal of the gate of the read transistor in the column of the storage units is the second low-level signal, a difference between a voltage of the second low-level signal and the second voltage is less than the threshold voltage of the read transistor, so as to turn off the read transistor whose storage signal is the second low-level signal, and a voltage of the second bit line connected to the turned-off read transistor maintains the second reference voltage.

12. The data operation method according to claim 11, wherein a difference between the voltage of the second high-level signal and the third reference voltage is less than the threshold voltage of the read transistor, so as to turn off the read transistors in other columns; and
a difference between the third reference voltage and the voltage of the second low-level signal is less than the threshold voltage of the write transistor, and a difference between the third reference voltage and the fourth reference voltage is less than the threshold voltage of the write transistor, so as to turn off each of the write transistors.

13. The data operation method according to claim 10, wherein both the read transistor and the write transistor are P-type transistors;
the storage signal comprises a second high-level signal and a second low-level signal, and a difference between the voltage of the second low-level signal and the second reference voltage is greater than the threshold voltage of each of the read transistors, so as to turn off each of the precharged read transistors;
when the storage signal of the gate of the read transistor in the column of the storage units is the second low-level signal, a difference between the voltage of the second low-level signal and the second voltage is less than the threshold voltage of the read transistor, so as to turn on the read transistor whose storage signal is the second low-level signal, and a voltage of the second bit line connected to the turned-on read transistor changes from the second reference voltage to the second voltage; and
when the storage signal of the gate of the read transistor in the column of the storage units is the second high-level signal, a difference between the voltage of the second high-level signal and the second voltage is greater than the threshold voltage of the read transistor, so as to turn off the read transistor whose storage signal is the second high-level signal, and a voltage of the second bit line connected to the turned-off read transistor maintains the second reference voltage.

14. The data operation method according to claim 13, wherein a difference between the voltage of the second low-level signal and the third reference voltage is greater than the threshold voltage of the read transistor, so as to turn off the read transistors in other columns; and
a difference between the third reference voltage and the voltage of the second high-level signal is greater than the threshold voltage of the write transistor, and a difference between the third reference voltage and the fourth reference voltage is greater than the threshold voltage of the write transistor, so as to turn off each of the write transistors.

15. The data operation method according to claim 11, wherein the third reference voltage and the fourth reference voltage are half a difference between the voltage of the second high-level signal and the voltage of the second low-level signal.
